(19) United States
(12) Patent Application Publication
(10) Pub. No.: US 2023/0238611 A1
(43) Pub. Date: Jul. 27, 2023

(54) BATTERY PACK DESIGN FOR PHASE CHANGE MANAGEMENT

(71) Applicant: Baidu USA LLC, Sunnyvale, CA (US)

(72) Inventor: TIANYI GAO, San Jose, CA (US)

(21) Appl. No.: 17/584,629

(22) Filed: Jan. 26, 2022

(51) Int. Cl. H01M 10/6569; H05K 7/20; H01M 10/613; H01M 10/6568; H01M 50/271; H01M 10/48

(52) U.S. Cl. CPC H01M 10/6569; H05K 7/203; H05K 7/20318; H05K 7/20327; H01M 10/613; H01M 10/6568; H01M 50/271; H01M 10/482

(57) ABSTRACT

A battery chassis for immersion cooling includes one or more groups of battery cells, an inlet, a condenser, and one or more fluid connectors disposed on the top of the chassis. For example, an inlet is disposed on a bottom of the chassis to receive two-phase cooling fluid from an immersion container, and the two-phase cooling fluid is to extract heat from the one or more battery cells and to transform from a liquid form into a vapor. A condenser is disposed on a top of the chassis to condense the vapor contained within the chassis of the two-phase fluid back into the liquid form. One or more fluid connectors disposed on the top of the chassis to connect the condenser with external cooling fluid via a liquid line, and the battery chassis is to be at least partially submerged in the two-phase cooling fluid of the immersion container.

### FIELD OF THE INVENTION

Embodiments of the present invention generally relate to electronics cooling, battery hardware, battery backup package, and phase change cooling. More particularly, embodiments of the invention relate to a battery pack design for phase change management.

### BACKGROUND

Cooling is a prominent factor in a computer system and data center design. The number of high performance electronics components such as high performance processors packaged inside servers has steadily increased, thereby increasing the amount of heat generated and dissipated during the ordinary operations of the servers. The reliability of servers used within a data center decreases if the environment in which they operate is permitted to increase in temperature over time. Maintaining a proper thermal environment is critical for normal operations of these servers in data centers, as well as the server performance and lifetime. It requires more effective and efficient cooling solutions especially in the cases of cooling these high performance servers.

Heat removal is a prominent factor in a computer system and data center design. The number of high performance electronics components such as high performance processors packaged inside servers have steadily increased, thereby increasing the amount of heat generated and dissipated during the ordinary operations of the servers. The reliability of servers used within a data center decreases if the environment in which they operate is permitted to increase in temperature over time. Maintaining a proper thermal environment is critical for normal operations of these servers in data centers, as well as the server performance and lifetime. It requires more effective and efficient heat removal solutions especially in the cases of cooling these high performance servers.

Previous solutions for battery cell packs are mostly air cooling or liquid cooling. These solutions may not enable high power density and high packaging densities.

### BRIEF DESCRIPTION OF THE DRAWINGS

Embodiments of the invention are illustrated by way of example and not limitation in the figures of the accompanying drawings in which like references indicate similar elements.

FIGS. 1A-1C show an example design of a battery chassis according to an embodiment of the application.

FIG. 2 shows a function principle of an example battery chassis design according to an embodiment of the application.

FIG. 3 shows an additional example design of a battery chassis and internal cell arrays according to an embodiment of the application.

FIG. 4 shows an example of high density battery packages according to an embodiment of the application.

FIG. 5 shows an example IT enclosure coupling with the battery chassis according to an embodiment of the application.

FIG. 6 shows an example of the cooling system with the battery chassis according to an embodiment of the application.

### DETAILED DESCRIPTION

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” means that a particular feature, structure, or characteristic described in conjunction with the embodiment can be included in at least one embodiment of the invention. The appearances of the phrase “in one embodiment” in various places in the specification do not necessarily all refer to the same embodiment.

The present disclosure proposes a solution for designing and packaging a battery pack for high power IT systems. In particular, the present disclosure aims to provide high quality and an efficient thermal management solution for high density cells.

In addition, the following features and functions are included in the present disclosure: high power density energy units; high efficiency two phase coolant management systems; efficient vapor management and leakage prevention systems; accommodating for different server and IT systems; enhanced cell performance; ease of implementation; ease of service and maintenance; accommodating different backup power requirements; and high scalable design for different deployment scales.

The present application relates to a battery pack in which battery cells connected in groups and arrays are packaged within the chassis. The chassis is designed with one side as inlet and one side as connectors. The connector side is packaged with a sealing layer. The two phase coolant enters the pack only through the inlet. The pack is vertically mounted to the IT enclosure and is submerged within the IT enclosure. A condensing unit is packaged under the top sealing layer and the condensing unit is connected with the connectors. During operation, the cells are submerged in the coolant which causes a portion of the two phase coolant to vaporize during the charging and discharging states. The vapor is contained and condensed within the pack. The IT enclosure includes liquid and electric lines for connecting with the packs.

According to one aspect, a battery chassis for battery immersion cooling includes a main section and a lid section. The main section includes one or more battery cells, and an inlet disposed on a bottom of the main section to receive two-phase cooling fluid from an immersion container. The two-phase cooling fluid is to extract heat from the one or more battery cells and to transform from a liquid form into a vapor, wherein the main section is to be at least partially submerged in the two-phase cooling fluid of the immersion container. The lid section is positioned on top of the main section and includes a condenser to condense the vapor of the two-phase fluid back into the liquid form, and a pair of fluid connectors to fluidly connect the condenser with external cooling fluid via a pair of a supply line and return line.

In an embodiment, the two-phase cooling fluid is to extract heat from the one or more battery cells during charging or discharging. The lid section is configured as a separate module that is removable from the main section. When the lid section is closed onto the top of the main section, the lid section and a top portion of the main section form a vapor region to contain the vapor within the vapor region to allow the condenser to condense the vapor. The vapor is condensed and returned back to the liquid form within the lid section, and circulated back to the battery cells within the main section. The fluid connectors are connected with the condenser via a pair of flexible hoses. The fluid connectors are removably disposed on a top exterior surface of the lid section while being connected with the condenser.

In an embodiment, each of the fluid connectors can be moved away from the lid section by pulling the fluid connector and the respective flexible hose. When the fluid connector is released, the flexible hose can be retracted back into the lid section while leaving the fluid connector stopped at the top exterior surface. The battery chassis is mounted such that the battery cells are completely or substantially submerged in the two-phase cooling fluid, while the condenser remains above the two-phase cooling fluid.

According to another aspect, an immersion cooling system includes an immersion container to contain two-phase cooling fluid therein, a pair of a fluid supply line and a fluid return line disposed within a top portion of the immersion container, and one or more battery chassis at least partially submerged in the two-phase cooling fluid of the immersion container, where each of the battery chassis can be implemented as described above.

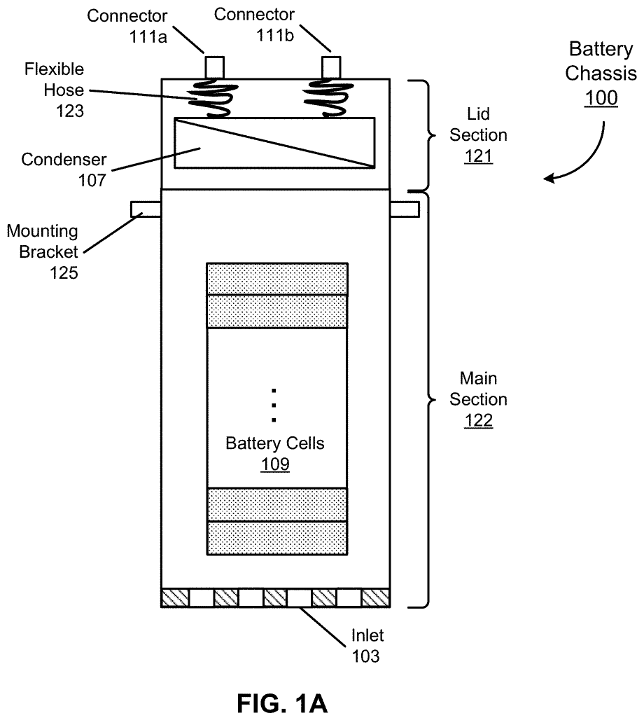

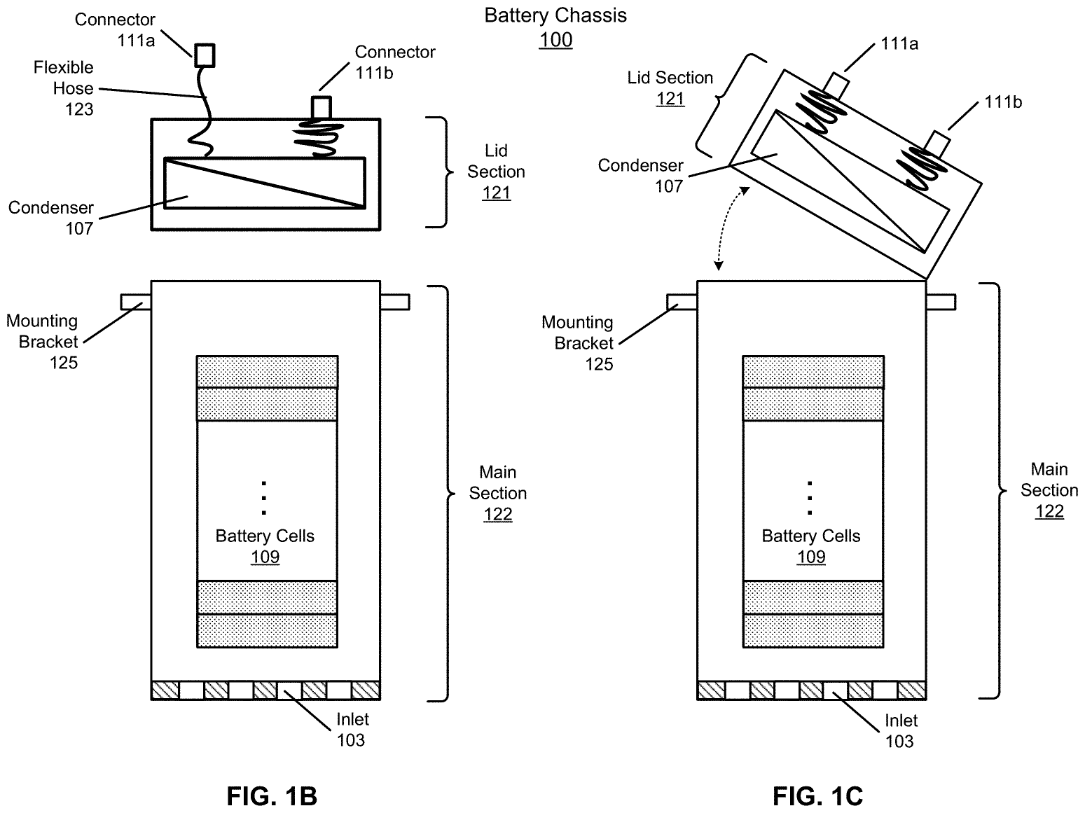

FIGS. 1A-1C show an example design of a battery chassis according to an embodiment of the application. Referring FIG. 1A, battery chassis 100 includes a lid section 121 and a main section 122. Battery chassis is configured to be vertically inserted and submerged into cooling fluid (e.g., two-phase cooling fluid) of an immersion container (also referred to as an immersion tank). The main section contains one or more battery cells 109 mounted therein. At the bottom of the main section 122, one or more inlets or openings 103 are disposed on the bottom surface of the main section 122. Such inlets allow the cooling fluid to enter the main section 122 when battery chassis 100 is submerged into the cooling fluid. Alternatively, main section 122 may not include the bottom panel (e.g., completely open) as long as battery cells 109 can be mounted within main section 122 without falling off. In one embodiment, battery cells 109 may be packaged in groups and arrays (referred to as battery packs), and physically and fixedly attached to the frame of the main section 122. This enables the cells to stay within the battery chassis with vertically mounted in the immersion container.

Lid section 121 is disposed on top of the main section 122, which forms an enclosed environment (e.g., sealed environment) at a top portion of the battery chassis 100. In one embodiment, lid section 121 includes a condenser 107 mounted therein. A pair of fluid connectors 111a-111b (collectively referred to as connectors 111) are connected to a supply connector or port and a return connector or port (not shown) of condenser 107 via a respective flexible hose, such as flexible hose 123. Connectors 111 may be used to connect condenser 107 to an external cooling source, for example, via an external fluid supply line or fluid return line to form a cooling loop. Condenser 107 may be an air-to-liquid heat exchanger.

In one embodiment, lid section 121 may be implemented as a separate module that can be removed from main section 122 as shown in FIG. 1B. Alternatively, lid section 121 may be implemented as part of a lid or cover of main section 122 as shown in FIG. 1C. Each of connectors 111 is disposed on an exterior surface (e.g., top surface) of lid section 121 while being connected to condenser 107 via a respective flexible hose or tube. In one embodiment, as shown in FIG. 1B, each of connectors 111 can be extended by pulling the connector and its corresponding flexible hose upwardly, for example, for the purpose of connecting the connector with an external liquid line. When the connector is released or disconnected from the external liquid line, the corresponding flexible hose is retracted into liquid section 121, while the connector is stopped at the exterior surface of lid section 121, as shown in FIG. 1A.

In one embodiment, referring back to FIG. 1A, main section 122 further includes one or more mounting brackets disposed on an exterior side surface(s) of main section 122 such as mounting bracket 123. In this example, there are at least two mounting brackets, one for each of the side surfaces of main section 122. A mounting bracket is used to mount the battery chassis onto an immersion container at a proper level. The location of the mounting bracket is designed to ensure the battery cells 109 can be completely or substantially submerged into the immersion cooling fluid within the immersion container, while lid section 121 remains above the fluid level of the immersion cooling fluid.

When battery chassis 100 is being submerged into two-phase cooling fluid, initially, lid section 121 may be removed or remain open, as shown in FIGS. 1B-1C, to allow the immersion cooling fluid of the immersion container to enter main section 122 from the bottom. After battery chassis 100 has been mounted, lid section 121 may then be closed onto the top of main section 122 to form an enclosed or sealed environment at the top, as shown in FIG. 1A. In one embodiment, there is a lock or latch mechanism between lid section 121 and main section 122 (not shown). When lid section 121 is position on top of main section 122, the lock mechanism can be activated, for example, by an operator or user, to securely lock and seal the lid section 121 with main section 122 to form a sealed enclosed environment.

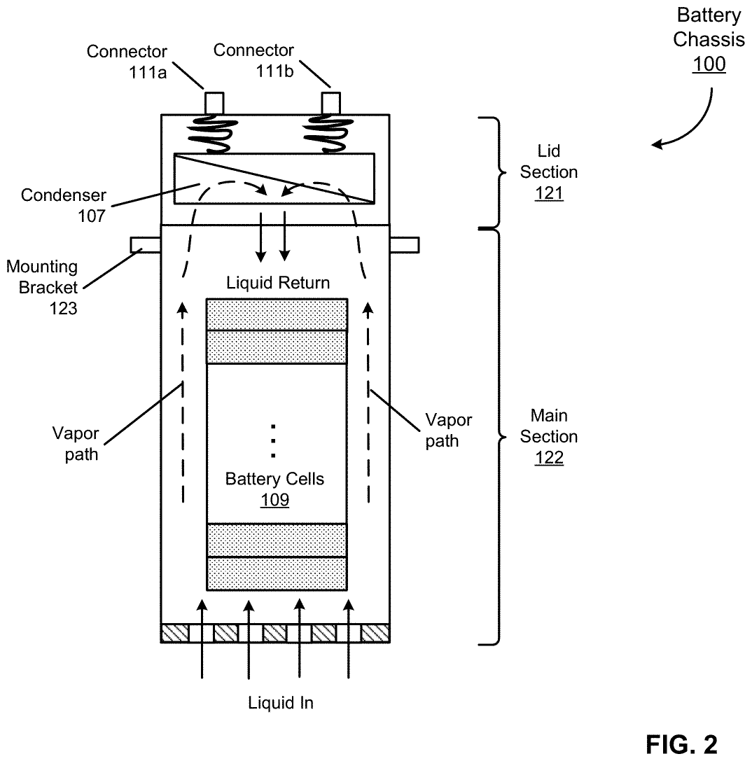

When battery chassis 100 is submerged into two-phase cooling fluid, referring now to FIG. 2, the battery cells 109 are expected to be completely submerged into the two-phase cooling fluid. The region submerged in the two-phase cooling fluid is referred to as a liquid region, while the space contained within the lid section 121 and above the fluid level is referred to as a vapor region. When battery cells 109 operate (e.g., charge or discharge) while being submerged into the two-phase cooling fluid, the two-phase cooling fluid extracts the heat generated from battery cells 109 and transforms from a liquid form into a vapor form. The vapor arises upwardly from the liquid region into the vapor region as represented by dash lines. Within the vapor region, the vapor is condensed by condenser 107 back into the liquid form, which then drops back into the liquid region within battery chassis 100 as represented by solid lines.

In particular, FIG. 2 shows the key function of the design that the phase change form liquid to vapor and vapor to liquid are both contained within the battery chassis 100. In an embodiment, the cells 109 cause the liquid to evaporate during charging and discharging. Further, the vapor is being contained within the battery chassis 100 and arises to the condensing location (e.g., vapor region). Furthermore, the vapor is being condensed back to liquid and return to the liquid region.

In an embodiment, the two-phase cooling fluid is to extract heat from the one or more battery cells 109 during charging or discharging. Further, battery chassis 100 is sealed with five sides (e.g., a top side, a front side, a back side, a right side and a left side) and only one side on the bottom forming the inlet to allow the two-phase cooling fluid enters the battery chassis according to an embodiment of the application.

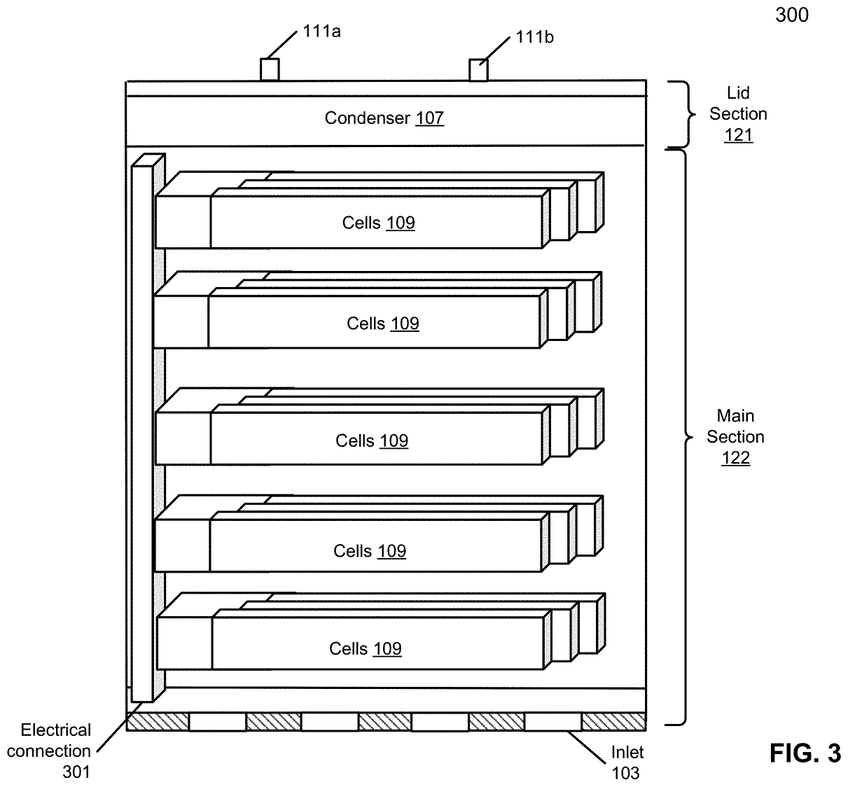

FIG. 3 shows an additional example design of a battery chassis 300 according to an embodiment of the application. In particular, FIG. 3 shows the battery pack design 300 including the electrical connection 301 that can be used to electrically connect external circuitries such as a power source for charging purpose or servers for discharging purpose. In an embodiment, design 300 considers the electrical connection (e.g., 301) from the bottom at the inlet side (e.g., 103). In addition, the top fluid connection (e.g., 111) is a schematic representation for connecting the condensing unit (e.g., 107) to external cooling fluid (not shown) according to an embodiment of the application.

According to FIG. 3, in an embodiment, the battery chassis includes one or more electrical connectors disposed at the bottom of the battery chassis and connected with the battery cells 109 for charging and discharging of the battery cells 109. Further, when the battery chassis is deposited into an immersion container, the electrical connectors are connected with counterpart electrical connectors of a power bus that is disposed at a bottom of the immersion container according to an embodiment of the application. Furthermore, the power bus is coupled to an external power source and one or more server chassis within the immersion container, such that the battery cells 109 can be charged from the power source or discharged to provide power to the server chassis via the power bus according to an embodiment of the application.

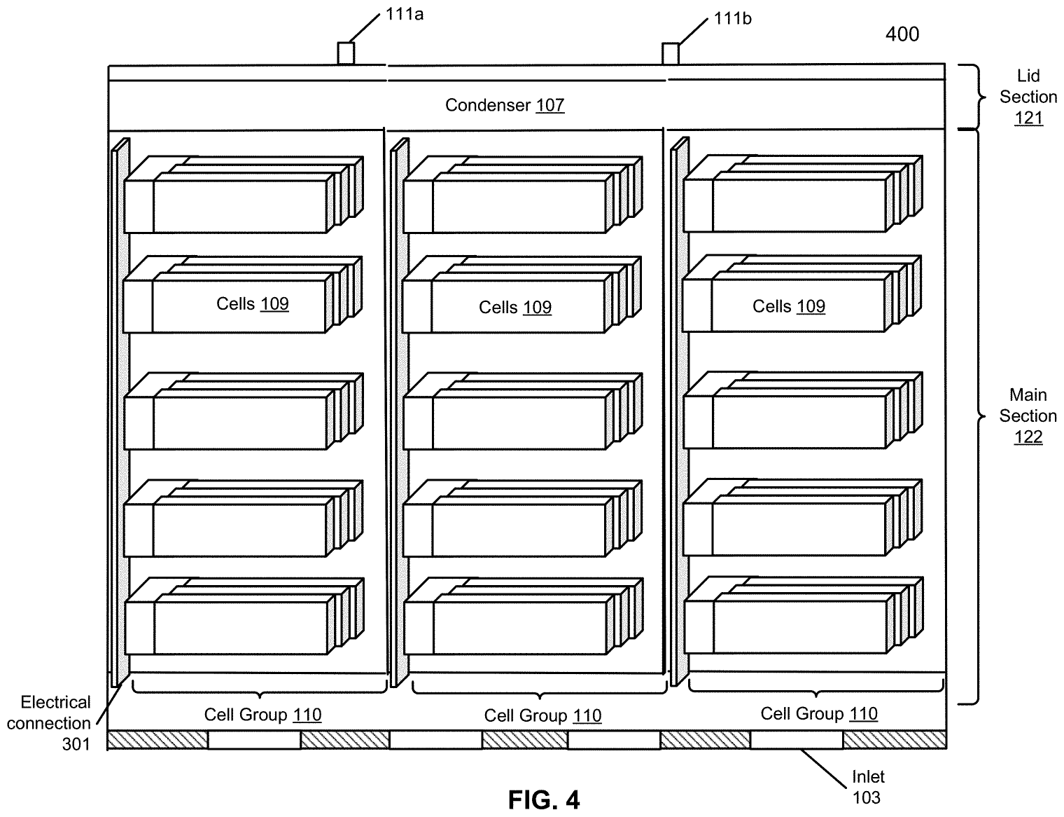

FIG. 4 shows an example of high density battery packages 400 according to an embodiment of the application. In particular, FIG. 4 shows design embodiment 400 that the entire chassis can be designed as an enclosure with the bottom side as the inlet 103 according to an embodiment of the application. For example, the inlet 103 can be either a perforated design or a full open design according to an embodiment of the application. Further, the chassis can be integrated with more than one groups of cells according to an embodiment of the application. Furthermore, the cell groups or battery packs 110 are packaged to the chassis and each of the groups may include separate electric connections according to an embodiment of the application. In addition, the condensing unit 107 is used for condensing the vapor contained within the entire chassis according to an embodiment of the application. Also, embodiment 400 shows high scalability according to an embodiment of the application. The design considers the battery chassis interoperability that with the same chassis, for packaging different groups and configurations cells arrays.

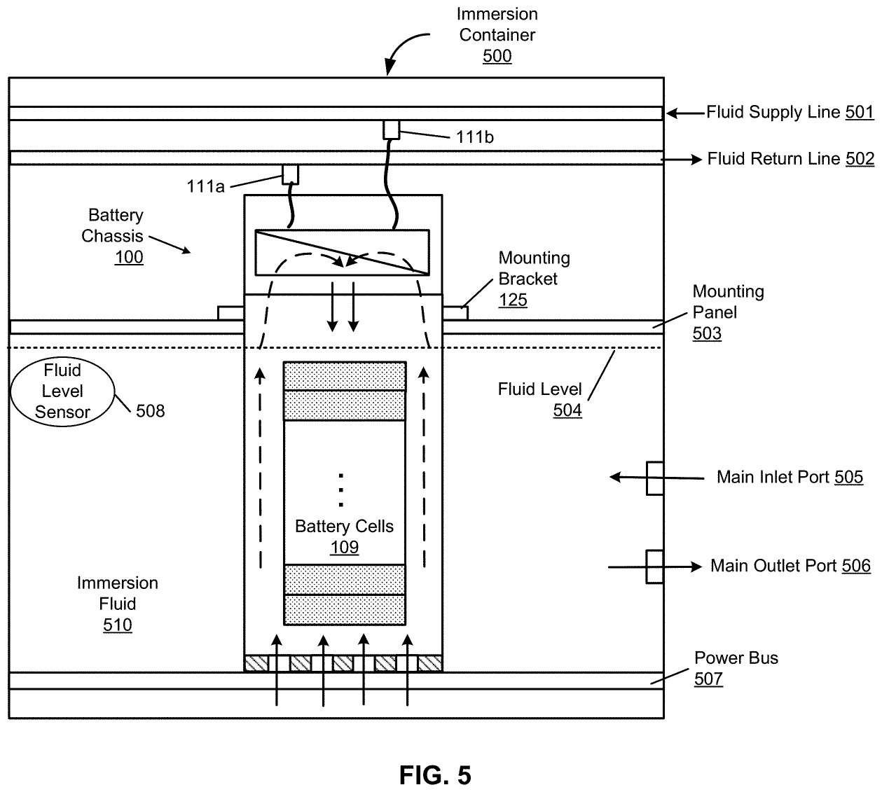

FIG. 5 shows an example of an immersion container for battery cooling according to one embodiment. Referring to FIG. 5, immersion container 500 includes a pair of fluid supply line 501 and fluid return line 502 disposed on a top portion of immersion container 500. The fluid supply line 501 and return line 502 may be coupled to an external cooling source such as facility supply and return lines or a cooler system. Immersion container 500 further includes a mounting structure, such as mounting panel 503, which is used to mount one or more battery chassis. Mounting panel 502 includes a number of slots corresponding to a number of battery chassis, each slot corresponding to one of the battery chassis. A slot allows a battery chassis to be deposited downwardly into and submerged in immersion fluid 510 maintained within immersion container 500.

In this example, battery chassis 100 is inserted through a slot or opening that is designed to accommodate a shape of battery chassis 100. Battery chassis 100 can be mounted onto mounting panel 503 using its mounting brackets such as mounting bracket 125. In one embodiment, the location or level of mounting panel 503 is designed for a specific type of battery chassis that is designed with a specific mounting bracket. As a result, when battery chassis 100 is inserted through a mounting slot, mounting bracket 125, which is fixedly attached to the battery chassis, is stopped or blocked by mounting panel 503 in view of fluid level 504 of immersion fluid 510, such that battery cells 109 are completely submerged in immersion fluid and below fluid level 504, while the lid section of the battery chassis remain above the fluid level 504. In addition, a fluid level sensor 508 may be deployed and monitored by a controller (not shown) to ensure a proper level of immersion fluid 510. Immersion fluid 510 (e.g., two-phase cooling fluid) may be circulated via main inlet port 505 and main outlet port 506, which may be coupled to an external cooling source. In an embodiment, since the fluid is balanced within each of the battery chassis, the main inlet port 505 and outlet port 506 are inactive during normal operation theoretically. They mainly designed for initial filling, dumping and making up purposes.

Once battery chassis 100 is deposited into a mounting slot of mounting panel 503, as described above, the lid section of battery chassis 100 can close to form an enclosed environment within a top portion of battery chassis 100 (e.g., vapor region). Connectors 111a and 111b can be pulled out and connect with corresponding counterpart connectors disposed on fluid supply line 501 and fluid return line 502 to form a cooling loop for the condenser disposed within the lid section. The cooling fluid, i.e., single-phase cooling fluid, such as water, can then be supplied to the condenser via fluid supply line 501 and fluid return line 502.

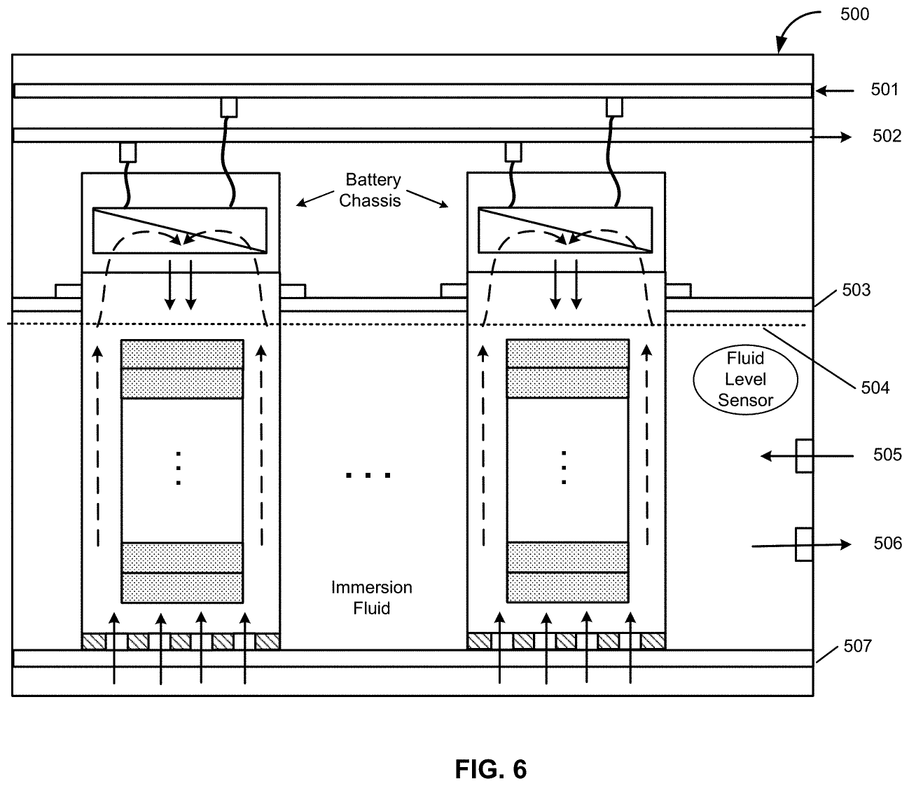

In one embodiment, immersion container 500 further includes power bus 507 disposed at or near the bottom of immersion container 500. Power bus 507 includes a number of pairs of electrical connectors. Each pair of connectors can be electrically coupled to a battery chassis when the battery chassis is inserted immersion container 500. As described above and shown in FIGS. 3-4, a battery chassis includes at least a pair of electrical connectors coupled to the battery cells. The electrical connectors of the battery chassis can be connected to the counterpart connectors of power bus 507. Power bus 507 may be coupled to an external power source for the purpose of charging the battery cells of the battery chassis. Power bus 507 may also be coupled to one or more server chassis, either in immersion container 500 or in another immersion container, for the purpose of discharging the battery cells. Although only one battery chassis is shown herein, it will be appreciated multiple battery chassis may also be inserted and submerged in the immersion container as shown in FIG. 6. Further, a combination of one or more battery chassis and server chassis may be maintained in the immersion container.

In the foregoing specification, embodiments of the invention have been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. A battery chassis for immersion cooling, comprising:
a main section, including:
one or more battery cells, and
an inlet disposed on a bottom of the main section to receive two-phase cooling fluid from an immersion container, wherein the two-phase cooling fluid is to extract heat from the one or more battery cells and to transform from a liquid form into a vapor, wherein the main section is to be at least partially submerged in the two-phase cooling fluid of the immersion container; and
a lid section positioned on top of the main section, the lid section including:
a condenser to condense the vapor of the two-phase fluid back into the liquid form, and
a pair of fluid connectors to fluidly connect the condenser with external cooling fluid via a pair of a supply line and return line.

2. The battery chassis of claim 1, wherein the two-phase cooling fluid is to extract heat from the one or more battery cells during charging or discharging.

3. The battery chassis of claim 1, wherein the lid section is configured as a separate module that is removable from the main section.

4. The battery chassis of claim 1, wherein when the lid section is closed onto the top of the main section, the lid section and a top portion of the main section form a vapor region to contain the vapor within the vapor region to allow the condenser to condense the vapor.

5. The battery chassis of claim 4, wherein the vapor is condensed and returned back to the liquid form within the lid section, and circulated back to the battery cells within the main section.

6. The battery chassis of claim 1, wherein the fluid connectors are connected with the condenser via a pair of flexible hoses.

7. The battery chassis of claim 6, wherein the fluid connectors are removably disposed on a top exterior surface of the lid section while being connected with the condenser.

8. The battery chassis of claim 7, wherein each of the fluid connectors can be moved away from the lid section by pulling the fluid connector and the respective flexible hose, and wherein when released, the flexible hose can be retracted back into the lid section while leaving the fluid connector stopped at the top exterior surface.

9. The battery chassis of claim 1, wherein the battery chassis is mounted such that the battery cells are completely submerged in the two-phase cooling fluid, while the condenser remains above the two-phase cooling fluid.

10. An immersion cooling system, comprising:
an immersion container to contain two-phase cooling fluid therein;
a pair of a fluid supply line and a fluid return line disposed within a top portion of the immersion container; and
one or more battery chassis at least partially submerged in the two-phase cooling fluid of the immersion container, each of the one or more battery chassis comprising:
a main section, including:
one or more battery cells, and
an inlet disposed on a bottom of the main section to receive two-phase cooling fluid from an immersion container, wherein the two-phase cooling fluid is to extract heat from the one or more battery cells and to transform from a liquid form into a vapor, wherein the main section is to be at least partially submerged in the two-phase cooling fluid of the immersion container; and
a lid section positioned on top of the main section, the lid section including:
a condenser to condense the vapor of the two-phase fluid back into the liquid form, and
a pair of fluid connectors to fluidly connect the condenser with the fluid supply line and the fluid return line.

11. The immersion cooling system of claim 10, wherein the two-phase cooling fluid is to extract heat from the one or more battery cells during charging or discharging.

12. The immersion cooling system of claim 10, wherein the lid section is configured as a separate module that is removable from the main section.

13. The immersion cooling system of claim 10, wherein when the lid section is closed onto the top of the main section, the lid section and a top portion of the main section form a vapor region to contain the vapor within the vapor region to allow the condenser to condense the vapor.

14. The immersion cooling system of claim 13, wherein the vapor is condensed and returned back to the liquid form within the lid section, and circulated back to the battery cells within the main section.

15. The immersion cooling system of claim 10, wherein the fluid connectors are connected with the condenser via a pair of flexible hoses.

16. The immersion cooling system of claim 15, wherein the fluid connectors are removably disposed on a top exterior surface of the lid section while being connected with the condenser.

17. The immersion cooling system of claim 16, wherein each of the fluid connectors can be moved away from the lid section by pulling the fluid connector and the respective flexible hose, and wherein when released, the flexible hose can be retracted back into the lid section while leaving the fluid connector stopped at the top exterior surface.

18. The immersion cooling system of claim 10, further comprising a mounting panel having a plurality of mounting slots, each of the mounting slots accommodating a shape of a specific battery chassis.

19. The immersion cooling system of claim 18, wherein when a battery chassis is mounted on the mounting panel, the battery cells are completely submerged in the two-phase cooling fluid, while the condenser remains above the two-phase cooling fluid.

20. The immersion cooling system of 19, further comprising a fluid level sensor disposed within the immersion container to maintain a proper level of the two-phase cooling fluid to ensure the battery cells to be completely submerged in the two-phase cooling fluid, while the condenser remains above the two-phase cooling fluid.
